(19) United States
(12) Patent Application Publication
(10) Pub. No.: US 2026/0247541 A1
(43) Pub. Date: Aug. 20, 2026

(54) METHOD FOR FABRICATING CURVED CONFORMAL MULTILAYER CIRCUIT BY ELECTRIC-FIELD-DRIVEN JET DEPOSITION MICRO-NANO 3-DIMENSIONAL PRINTING BASED ON CHARGE CONTROL AND SYSTEM THEREFOR

(71) Applicants: QINGDAO UNIVERSITY OF TECHNOLOGY, Qingdao (CN); QINGDAO 5D INTELLIGENT ADDITIVE MANUFACTURING TECHNOLOGY CO., LTD., Qingdao (CN)

(72) Inventors: Hongbo LAN, Qingdao (CN); Xiaoyang ZHU, Qingdao (CN); Houchao ZHANG, Qingdao (CN); Hongke LI, Qingdao (CN); Fan ZHANG, Qingdao (CN); Quan XU, Qingdao (CN); Jiawei ZHAO, Qingdao (CN)

(21) Appl. No.: 19/400,283

(22) Filed: Nov. 25, 2025

(30) Foreign Application Priority Data
Feb. 19, 2025 (CN) 2025101847403

(51) Int. Cl. H05K 3/12; H05K 3/00

(52) U.S. Cl. CPC H05K 3/125; H05K 3/0091; H05K 3/1283; H05K 2203/013; H05K 2203/105

(57) ABSTRACT

The present invention provides a method for fabricating a curved conformal multilayer circuit by an electric-field-driven (EFD) jet deposition micro-nano 3-dimensional (3D) printing based on charge control and a system therefor, wherein a high-precision conformal thin-film dielectric layer is formed through charge-injection electrowetting and contact EFD jet deposition micro-nano 3D printing; a high-resolution curved conformal circuit is fabricated by combining active residual charge elimination with non-contact EFD jet deposition micro-nano 3D printing; and by organically combining active charge control with the EFD jet deposition micro-nano 3D printing, high-precision conformal thin-film dielectric layers and conductive-layer conformal circuits and interlayer interconnect circuits thereof are printed in an integrated manner. The present invention achieves efficient, low-cost, high-precision, and uniform and consistent fabrication of the curved conformal multilayer circuit.

### CROSS-REFERENCE TO RELATED APPLICATIONS

The present invention claims priority to the Chinese Patent Application No. 202510184740.3, filed with the China National Intellectual Property Administration on Feb. 19, 2025, entitled "METHOD AND SYSTEM FOR FABRICATING CURVED CONFORMAL MULTILAYER CIRCUIT BY MICRO-NANO 3-DIMENSIONAL PRINTING BASED ON CHARGE CONTROL AND SYSTEM THEREFOR", the entire content of which is incorporated herein by reference and constitutes a part of the present invention for all purposes.

### TECHNICAL FIELD

The present invention belongs to the field of electronic fabrication and micro-nano 3D printing, and specifically relates to a method for fabricating a curved conformal multilayer circuit by an electric-field-driven (EFD) jet deposition micro-nano 3-Dimensional (3D) printing based on charge control and a system therefor.

### BACKGROUND

The statements in this section merely provide background information related to the present invention and do not necessarily constitute the prior art.

Curved conformal electronics are new cutting-edge 3D structural electronic products that have emerged in recent years with the progress of previous fabrication technologies (especially multi-material micro-nano 3D printing). It subverts the traditional concept where mechanical structures and electronic circuits of a product are separated from each other (designed and fabricated separately before being assembled). Mechanical structures and

electronic circuits are tightly integrated (conformal electronic circuits are fabricated on 3D structures or complex curved surfaces to organically integrate structures, functional circuits, and electronics, and unify structural and electronic functions). This not only helps create multifunctional, miniaturized, lightweight, and smart products, but also provides a brand-new solution for the development of disruptive innovative products. Currently, curved conformal electronics have been widely applied in various fields, such as biomedicine, automotive, wearable devices, health monitoring, and smart structures. Current typical conformal electronics and applications mainly include conformal antennas, frequency selective surface (FSS), structural electronics, 3D sensors, electronic skin, robots, microsystem integration, 3D packaging, etc. Curved conformal electronics generally include 3D substrates, medium layers (dielectric layers), conductive layers, interlayer interconnect circuits, packaging layers, etc.

At present, most curved conformal electronics are fabricated by directly patterning conductive layers on the substrate surface, i.e., patterning conformal electronics and circuits on the substrate surface, with little involvement of multilayer dielectric layers, multilayer conductive layers, or interlayer vertical interconnects. This severely limits the multifunctionality and high performance of curved conformal electronics. For example, existing FSS faces issues such as poor conformality, low wave transmission efficiency, narrow frequency response, and poor anti-interference capability, making it unable to solve the problem of transmitting multi-frequency and broadband electromagnetic waves. There is an urgent need to develop multilayer frequency selective surfaces (FSSs) based on multilayer structures. Traditional single-layer conformal antennas suffer from narrow bandwidth, and there is an urgent need to develop multilayer wideband conformal antennas to achieve multi-frequency communication. Therefore, many curved conformal electronic products, such as wideband omnidirectional conformal antennas, smart aircraft skin, curved multilayer printed boards, smart wearable devices, 3D structural electronics, structural health monitors, 3D sensors, smart structures, electromagnetic metamaterials, and soft robots, and their applications have a tremendous demand for 3D circuits and curved conformal multilayer circuits. In particular, the fabrication of complex curved conformal multilayer circuits is the key core technology for creating these high-performance curved conformal electronic products.

Currently, domestic and foreign scholars have proposed various fabrication technologies for curved conformal electronic circuits, mainly including: (1) conformal transfer printing technology; (2) LPKF-LDS laser direct structuring by German company LPKF; (3) five-axis laser

etching; (4) aerosol jet printing by American company Optomec; (5) inkjet printing; (6) electrohydrodynamic jet printing; (7) local polarization electric field driven vertical jet curved conformal micro-nano 3D printing; (8) curved surface photolithography; and (9) extrusion-based direct writing. In addition, there are multi-axis linkage machining, holographic lithography, and other technologies. However, these existing technologies face challenges in fabrication of conformal electronic circuits on non-developable, variable-curvature, or multi-curvature complex curved surfaces; and they have issues like poor bonding strength at the interfaces between conformal circuits and substrates, and low interlayer positioning accuracy. Additionally, existing curved conformal circuit fabrication technologies are unable to achieve high-precision dielectric layer thin film fabrication. In particular, the fabrication of high-precision ultra-thin dielectric layers (for high-precision 3D sensors, wearable devices, etc.) and ultra-thick dielectric layers (for multilayer FSS, conformal antennas, etc.) currently fails to meet actual engineering requirements at all.

In summary, current curved conformal multilayer circuit fabrication mainly faces the following difficulties: (1) existing fabrication technology cannot achieve fabrication of high-precision and uniform curved dielectric layers (conformal thin films), resulting in the inability to fabricate curved conformal multilayer circuits; (2) it is difficult or even impossible to fabricate high-resolution and high-performance conformal circuits on non-developable, multi-curvature, or other complex curved substrates; (3) existing curved surface printing technology has issues such as droplet sliding and spreading (when printing low-viscosity materials), poor uniformity, low precision, poor electrical performance, and weak interface bonding strength; and (4) it is difficult to fabricate vertical interconnects in curved multilayer circuits. Therefore, existing technology cannot achieve fabrication of high-precision curved conformal multilayer circuits, especially that on non-developable surfaces and multi-curvature surfaces. There is an urgent need in both academia and industry to develop new fabrication technologies to achieve efficient, low-cost, and highly consistent fabrication of high-resolution, high-performance (high-conductivity, high-adhesion), and high-precision curved conformal multilayer circuits on non-developable, multi-curvature, and other complex curved substrates.

### SUMMARY

To solve the above problems, the present invention provides a novel method for fabricating a curved conformal multilayer circuit by an EFD jet deposition micro-nano 3D printing based on charge control. In this method, a high-precision conformal thin-film dielectric layer is formed by combining charge-injection electrowetting with EFD jet deposition micro-nano 3D printing; and a high-resolution curved conformal circuit is fabricated by combining active residual charge elimination with non-contact EFD jet deposition micro-nano 3D printing. By organically combining active charge control with EFD jet deposition micro-nano 3D printing, high-precision conformal thin films and conformal circuits are simultaneously printed in an integrated manner, thus achieving efficient and low-cost fabrication of the high-precision curved conformal multilayer circuit.

A method for fabricating a curved conformal multilayer circuit by an EFD jet deposition micro-nano 3D printing based on charge control and a system therefor, can achieve efficient and low-cost fabrication of the high-precision curved conformal multilayer circuit.

According to some embodiments, the present invention adopts the following technical solutions:

A method for fabricating a curved conformal multilayer circuit by an EFD jet deposition micro-nano 3D printing based on charge control, including the following steps:

Step (1), pretreatment of a substrate comprises performing a degreasing and decontaminating treatment on a substrate (a curved three-dimensional model formed by 3D printing, cutting, injection molding, etc.), and then fixing the substrate after the treatment to a printing platform.

Step (2), printing of a dielectric layer, comprises selecting a suitable dielectric material (polyimide (PI), polytetrafluoroethylene (PTFE), a liquid crystal polymer (LCP), resin, polydimethylsiloxane (PDMS), or the like) according to design requirements, placing a prepared printing material into a conformal thin-film dielectric layer printing nozzle (a conductive nozzle is used, and the nozzle is connected to a positive electrode of a high-voltage power supply), and printing a first dielectric layer through a charge injection and EFD jet deposition micro-nano 3D printing process in combination with optimized process parameters (a voltage, a printing speed, a back pressure, a printing height, or the like). Fabricating a high-precision curved conformal thin-film dielectric layer through active charge injection and a charge-injection electrowetting effect in combination with EFD jet deposition micro-nano 3D printing.

Step (3), elimination of residual charge, comprises eliminating the residual charge in the printed dielectric layer and the substrate using a micro electrostatic eliminator or the like.

Step (4), printing of a conductive-layer conformal circuit, comprises selecting suitable conductive ink (nano silver paste/silver ink, carbon paste, a conductive polymer, or the like), placing the selected conductive ink into a conformal circuit printing nozzle (a glass or ceramic insulating nozzle is used, and an extraction electrode disposed on an outer side of the nozzle is connected to a positive electrode of a high-voltage power supply), and printing a first conductive-layer conformal circuit through a non-contact EFD jet deposition micro-nano 3D printing process in combination with the optimized process parameters (the voltage, the printing speed, the back pressure, the printing height, or the like). By using the non-contact EFD jet deposition micro-nano 3D printing process and the insulating nozzle made of glass, due to no charge injection, the crosstalk is reduced, the printing stability is improved, and the fabrication of a high-resolution and high-density curved conformal microcircuit is achieved. The printed circuit is made conductive through curing and sintering treatments.

Step (5), printing of a dielectric layer, comprises printing a second (or next) dielectric layer by performing the step (2) again.

Step (6), fabricating of vertical interconnect vias, comprises fabricating a plurality of vertical interconnect microvias in the second dielectric layer by using a laser printing module.

Step (7), elimination of the residual charge, comprises performing step (3) again.

Step (8), printing of a conductive-layer conformal circuit and filling of the vertical interconnect vias, comprises printing a second conductive-layer conformal circuit by performing the step (4) again; then, printing a circuit for filling the vertical interconnect vias to complete a fabrication of a vertical interconnect circuit; and then, making the printed conformal circuit conductive through curing and sintering treatments.

Step (9), repeating steps (5) to (8) to complete a fabrication of all curved conformal dielectric layers and conductive-layer conformal circuits and interlayer vertical interconnect circuits.

Step (10), printing a packaging layer.

And, step (11), performing a post-treatment.

As an optional embodiment, in the step (1), a material of the substrate includes, but is not limited to, ceramic, polyetheretherketone (PEEK), plastic, glass, resin, silicone, metal, or the

like, and a shape of the substrate includes, but is not limited to, any 3D curved geometric shape of a developable curved surface or a non-developable curved surface.

As an optional embodiment, in the step (2), the dielectric material includes, but is not limited to, at least one of polyimide (PI), polytetrafluoroethylene (PTFE), a liquid crystal polymer (LCP), resin, polydimethylsiloxane (PDMS), and ceramic, with a viscosity range of 1-50,000 cps.

As an optional embodiment, in the step (2), the charge injection and the EFD jet deposition micro-nano 3D printing process are employed, and a conductive nozzle is directly connected to a high-voltage power supply. Printing parameters includes a printing voltage of -5,000 V to +5,000 V, a printing air pressure of 0-500 kPa, a printing speed of 0-80 mm/s, and a printing height of 0.04-3 mm.

As an optional embodiment, in the step (4), a conductive material includes at least one of nano silver ink/silver paste, conductive copper ink/copper paste, silver nanowire ink, carbon paste, and a conductive polymer, with a viscosity range of 1-50,000 cps.

As an optional embodiment, in the step (4), the non-contact EFD jet deposition micro-nano 3D printing process is employed, a glass or ceramic insulating nozzle is adopted, and an extraction electrode disposed on an outer side of the nozzle is connected to a positive electrode of a high-voltage power supply. Printing parameters includes a printing voltage of -3,000 V to +3,000V, a printing air pressure of 0-300 kPa, a printing speed of 0-50 mm/s, and a printing height of 0.03-0.5 mm.

As an optional embodiment, in the step (8), a high-solid-content stretchable conductive material is preferably selected as the printing material and includes at least one of stretchable silver paste, stretchable carbon paste, and a conductive polymer, with a solid content greater than 60% and a viscosity range of 0-50,000 cps. Printing parameters include a printing voltage of 0-2,000 V, a printing air pressure of 0-500 kPa, and a printing speed of 0-20 mm/s.

A system for fabricating a curved conformal multilayer circuit by an EFD jet deposition micro-nano 3D printing based on charge control, including a five-axis linkage micro-nano 3D printer, a laser drilling module, and a control system.

The five-axis linkage micro-nano 3D printer includes a single-potential contact electric field conductive nozzle (a conformal thin-film printing nozzle), a non-contact electric field nozzle (a conformal circuit printing nozzle), and an electrostatic eliminator.

The single-potential contact electric field conductive nozzle (the conformal thin-film dielectric printing nozzle) includes a barrel, an adapter, and a printing nozzle, where the

conductive printing nozzle is disposed at a tail end of the barrel, the adapter is disposed at an upper end of the barrel, and the barrel is connected to an air pressure module.

The non-contact electric field nozzle (the conformal circuit printing nozzle) includes a barrel, an adapter, a printing nozzle, and an annular electrode, where the printing nozzle is disposed at a tail end of the barrel, the annular electrode is sleeved outside the printing nozzle, the adapter is disposed at an upper end of the barrel, and the barrel is connected to an air pressure module.

The electrostatic eliminator is arranged side by side with the single-potential contact electric field conductive nozzle and the non-contact electric field nozzle, or is automatically switched using a dedicated device.

As an optional embodiment, an optional range for an inner diameter of the printing nozzle of the single-potential contact electric field conductive nozzle is 0.1-0.6 mm, and the printing nozzle is made of a conductive material and is externally connected to a high-voltage power supply with an adjustable range of -5,000 V to +5,000 V.

As an optional embodiment, the printing nozzle of the non-contact electric field nozzle is made of a non-conductive material, and the annular electrode is fixed on an outer side of the printing nozzle without direct contact with a printing material.

As an optional embodiment, an optional range for an inner diameter of the printing nozzle of the non-contact electric field nozzle is 0.1-0.6 mm, and the annular electrode is connected to a high-voltage power supply with an adjustable range of -5,000 V to +5,000 V.

As an optional embodiment, a pressure range of the air pressure module is 0-500 kPa.

Compared with the prior art, the present invention has the following beneficial effects:

The present invention solves the problem with fabrication of the high-resolution curved conformal multilayer circuit on any complex curved surface (especially non-developable, multi-curvature, or other complex curved surfaces).

The present invention can achieve efficient and low-cost fabrication of the high-precision curved conformal multilayer circuit.

The present invention can achieve high-precision fabrication of curved conformal thin films, thereby solving the problem with conformal fabrication of complex curved dielectric layers.

The fabrication method in the present invention has outstanding advantages of low cost, high precision, and broad adaptability.

The present invention achieves efficient, low-cost, high-precision, and uniform and consistent fabrication of the curved conformal multilayer circuit, and particularly provides a brand-new solution with industrial application prospects for many curved conformal electronic products, such as wideband FSS high-stealth radomes, wideband omnidirectional conformal antennas, smart aircraft skin, curved multilayer printed boards, smart wearable devices, 3D structural electronics, structural health monitors, 3D sensors, smart structures, electromagnetic metamaterials, and soft robots, and their applications.

To make the above objectives, features, and advantages of the present invention more comprehensible, detailed descriptions are provided below with reference to preferred embodiments and accompanying drawings.

### BRIEF DESCRIPTION OF THE DRAWINGS

The accompanying drawings constituting a part of the present invention are used to provide further understanding of the present invention. The schematic embodiments of the present invention and their descriptions are used to explain the present invention and do not constitute an improper limitation to the present invention.

FIG. 1 is a schematic diagram of a method for fabricating a curved conformal multilayer circuit by an EFD jet deposition micro-nano 3D printing based on charge control in the present invention.

FIG. 2A is a principle diagram of a charge-injection electrowetting effect in Example 2 of the present invention.

FIG. 2B is a principle diagram of a charge-injection electrowetting effect in Example 3 of the present invention.

FIG. 3 is a principle diagram of a non-contact EFD jet deposition micro-nano 3D printing in the present invention.

FIG. 4 is a schematic structural diagram of a conductive conformal thin-film dielectric layer printing nozzle in the present invention.

FIG. 5 is a schematic structural diagram of a conformal circuit printing nozzle in the present invention.

FIG. 6 is a flowchart of a process of fabricating a curved conformal multilayer circuit by an EFD jet deposition micro-nano 3D printing based on charge control in the present invention.

In the drawings: 1, air pressure module; 2, adapter; 3, barrel; 4, printing nozzle; and, 5, annular electrode.

### DETAILED DESCRIPTION

The present invention will be further described below in conjunction with the accompanying drawings and embodiments.

It should be noted that the following detailed descriptions are all exemplary and are intended to provide further illustration of the present invention. Unless otherwise specified, all the technical and scientific terms used in the present invention have the same meanings as those commonly understood by those of ordinary skill in the art to which the present invention belongs.

It is to be noted that the terms used herein are only for describing specific embodiments, and are not intended to limit exemplary embodiments according to the present invention. As used herein, unless otherwise indicated by context, a singular form is intended to also include a plural form. Additionally, it should be understood that when the term "include/including" and/or "comprise/comprising" is used in this specification, it indicates the presence of features, steps, operations, devices, assemblies, and/or their combinations.

In the absence of a conflict, the examples in the present invention can be combined with the features in the examples.

### Example 1

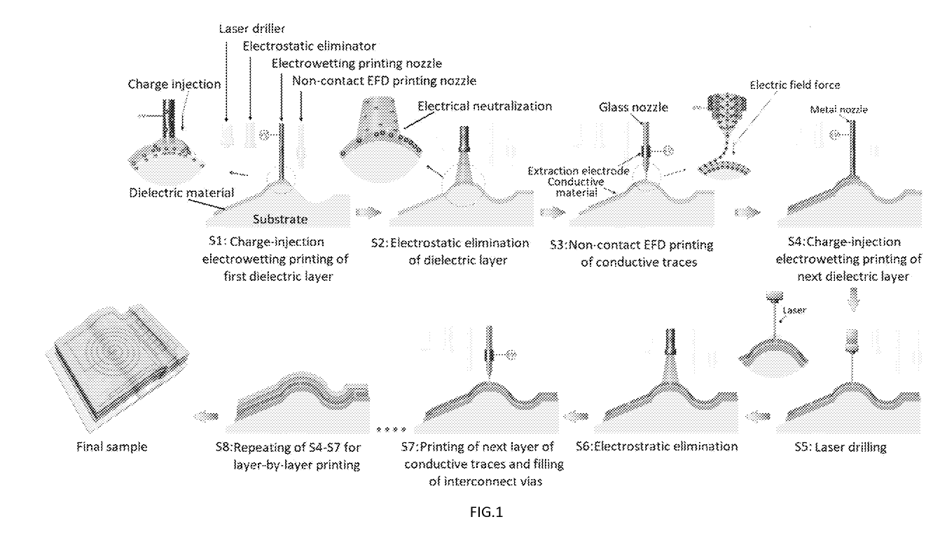

A method for fabricating a curved conformal multilayer circuit by an EFD jet deposition micro-nano 3D printing based on charge-injection electrowetting is as shown in FIG. 1 and mainly includes the following steps.

Step (1), pretreatment of a substrate: first, the substrate (a curved three-dimensional model formed by 3D printing, cutting, injection molding, etc.) is degreased and decontaminated; then, processing codes are generated according to a required circuit pattern and input to a five-axis linkage micro-nano 3D printer.

Step (2), printing of a dielectric layer: a suitable dielectric material (polyimide (PI), polytetrafluoroethylene (PTFE), a liquid crystal polymer (LCP), resin, polydimethylsiloxane (PDMS), or the like) is selected according to design requirements, a prepared dielectric material is placed into a conformal thin-film dielectric layer printing nozzle (a conductive nozzle is used, and the nozzle is connected to a positive electrode of a high-voltage power supply), and a first dielectric layer is printed through a charge injection and an EFD jet deposition micro-nano 3D printing process in combination with optimized process parameters (a voltage, a printing speed, a back pressure, a printing height, or the like). A high-precision curved conformal thin-film dielectric layer is fabricated through active charge injection and a charge-injection electrowetting effect in combination with the EFD jet deposition micro-nano 3D printing, and the dielectric layer is cured by means of heat or UV curing.

In step (3), residual charge is eliminated: the residual charge in the printed dielectric layer and the substrate is eliminated using an electrostatic eliminator on the five-axis linkage micro-nano 3D printer.

Step (4), printing of a (first-layer) conductive-layer conformal circuit: suitable conductive ink (nano silver paste/silver ink, carbon paste, a conductive polymer, or the like), the conductive ink is placed into a conformal circuit printing nozzle (a glass or ceramic insulating nozzle is used, and an extraction electrode disposed on an outer side of the nozzle is connected to a positive electrode of a high-voltage power supply), and a first conductive-layer conformal circuit is printed through a non-contact EFD jet deposition micro-nano 3D printing process in combination with the optimized process parameters (the voltage, the printing speed, the back pressure, the printing height, or the like). By using the non-contact EFD jet deposition micro-nano 3D printing process and the insulating nozzle made of glass, due to no charge injection, the crosstalk is reduced, the printing stability is improved, and the fabrication of a high-resolution and high-density curved conformal microcircuit is achieved. The printed conformal circuit is made conductive through curing and sintering treatments.

Step (5), printing of a second (or next) dielectric layer: the operation of step (2) is repeated.

Step (6), fabricating of vertical interconnect vias: a plurality of vertical interconnect microvias are fabricated in the second dielectric layer by using a laser printing module.

Step (7), elimination of the residual charge: the operation of step (3) is performed.

Step (8), printing of a conductive-layer conformal circuit and filling of the vertical interconnect vias: the operation of step (4) is performed to print a second conductive-layer circuit. Subsequently, a circuit filling vertical interconnect vias is printed to complete fabrication of a vertical interconnect circuit. Finally, the printed circuit is made conductive through curing and sintering treatments.

Step (9): the operations of step (5) to step (8) are repeated to complete fabrication of all curved conformal dielectric layers and conductive-layer conformal circuits.

Step (10), printing a packaging layer: the circuit is packaged using a packaging material as a printing material.

Step (11), post-treatment: relevant electronic components, feed connectors, etc., can be connected as needed, followed by post-curing, sintering, and other treatments.

In some other examples, in the step (1), a material of the substrate includes, but is not limited to, ceramic, PEEK, plastic, glass, resin, silicone, metal, or the like, and a shape of the substrate includes, but is not limited to, any 3D curved geometric shape of a developable curved surface or a non-developable curved surface.

In some other examples, in the step (2), the dielectric material includes, but is not limited to, polyimide (PI), resin, ceramic, polydimethylsiloxane (PDMS), or the like, with a viscosity range of 1 – 50,000 cps.

In some other examples, in the step (2), printing parameters includes a printing voltage of -5,000 V to +5,000 V, a printing air pressure of 0 – 500 kPa, a printing speed of 0 – 80 mm/s, and a printing height of 0.04 – 3 mm.

In some other examples, in the step (4), a conductive material includes nano silver ink/silver paste, conductive copper ink/copper paste, silver nanowire ink, carbon paste, or a conductive polymer, with a viscosity range of 1 – 50,000 cps.

In some other examples, in the step (4), printing parameters includes a printing voltage of -3,000 V to +3,000 V, a printing air pressure of 0 – 300 kPa, a printing speed of 0 – 50 mm/s, and a printing height of 0.03 – 0.3 mm.

In some other examples, the curing in the steps (2), (4), (5), and (8) includes, but is not limited to, heat curing, ultraviolet curing, infrared curing, and chemical curing.

### Example2

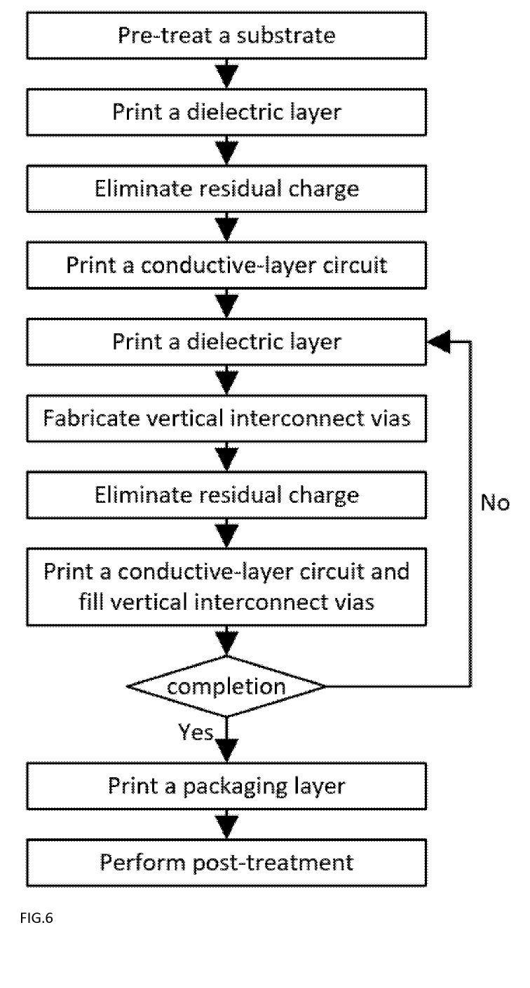

A method for fabricating a curved conformal multilayer frequency selective surface device by an EFD jet deposition micro-nano 3D printing based on charge-injection electrowetting is as shown in FIG. 6.

In the present example, a hemispherical polytetrafluoroethylene (PTFE) substrate with a radius of 10 cm is selected, a structure of a printed circuit is a multilayer frequency selective surface, a dielectric material is polyimide (PI), and a conductive material is nano silver paste. The specific implementation steps are as follows.

In step 1, a substrate is pretreated. First, the PTFE substrate is cleaned to remove surface impurities; then, a scanner is used to perform digital reverse engineering on the printed substrate, a processing model is built, and processing codes are generated according to a required circuit pattern and input to a five-axis linkage micro-nano 3D printer.

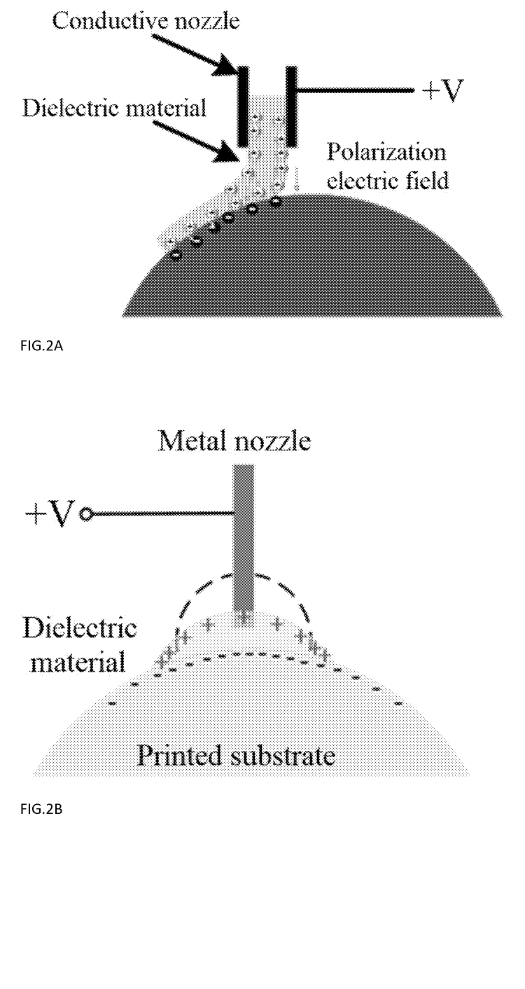

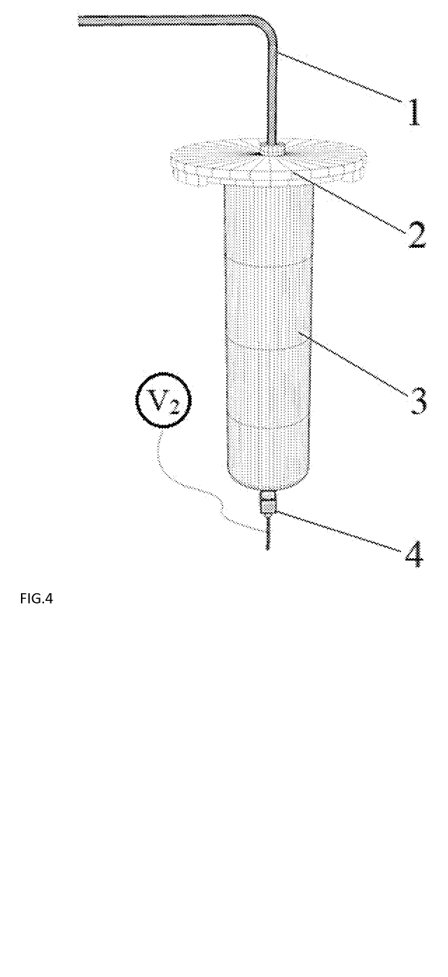

In step 2, a first PI dielectric layer is printed: a PI solution is used as a printing material, the prepared printing material is placed into a conformal thin film printing nozzle (a stainless steel conductive nozzle is used, and the nozzle is connected to a positive electrode of a high-voltage power supply), and a charge injection and an EFD jet deposition micro-nano 3D printing process are employed, as shown in FIG. 4. The printing nozzle is moved to a printing start point on the substrate, the single-potential nozzle is connected to the positive electrode of the high-voltage power supply, printing parameters (a nozzle inner diameter of 0.1 mm, a printing height of 0.1 mm, a printing voltage of 2,000 V, a printing air pressure of 100 kPa, and a workbench movement speed of 20 mm/s) are set, a printing path is loaded, and under a charge-injection electrowetting effect, a first PI dielectric thin film layer is conformally printed on the surface of the PTFE substrate, as shown in FIG. 2A. The dielectric layer is cured by heating.

In step 3, residual charge is eliminated: the residual charge in the printed dielectric layer and the substrate is eliminated using an electrostatic eliminator on the five-axis linkage micro-nano 3D printer.

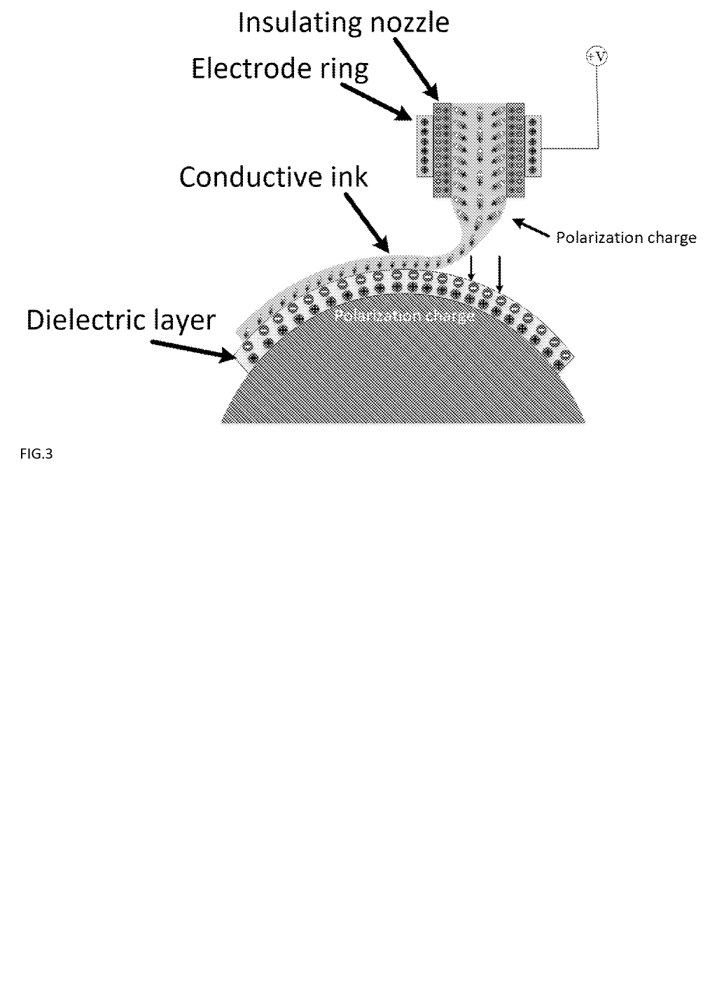

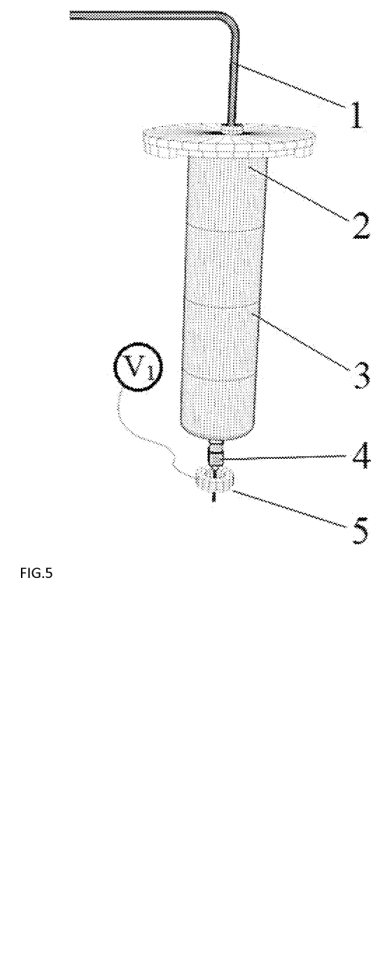

In step 4, a first conformal circuit layer is printed: conductive nano silver paste is used as a printing material, the printing material is placed into a conformal circuit printing nozzle (a glass nozzle is used, and an extraction electrode disposed on an outer side of the nozzle is connected to a positive electrode of a high-voltage power supply), and a non-contact EFD jet deposition micro-nano 3D printing process is employed, as shown in FIG. 5. The printing nozzle is moved to a printing start point on a circuit, printing parameters (a nozzle inner diameter of 0.05 mm, a printing height of 0.08 mm, a printing voltage of 2,000 V, a printing air pressure of 200 kPa, and a workbench movement speed of 40 mm/s) are set, a printing path is loaded, and the conductive material is formed into a Taylor cone under a self-excited electrostatic field effect to achieve conformal printing of the high-precision circuit, as shown in FIG. 3. Due to no charge injection, the crosstalk is reduced, the printing stability is improved, and the fabrication of a high-resolution and high-density curved conformal microcircuit is achieved. Printed conductive traces are made conductive through heat curing and sintering treatments.

In step 5, since there is no interlayer interconnect in the present example, printing interlayer vertical interconnect circuits is unnecessary. Steps 2 to 4 are directly repeated to complete fabrication of all dielectric layers and conductive-layer conformal circuits.

In step 6, a packaging layer is printed and post-treatment is performed. After printing is completed, an anti-oxidation coating is applied to the multilayer frequency selective surface device.

In some other examples, in step 1, a material of the substrate includes, but is not limited to, ceramic, PEEK, plastic, glass, resin, silicone, metal, or the like, and a shape of the substrate includes, but is not limited to, any 3D curved geometric shape of a developable curved surface or a non-developable curved surface.

In some other examples, in step 2, the dielectric material includes, but is not limited to, one of ceramic, polydimethylsiloxane (PDMS), and the like.

In some other examples, in step 2, the printing parameters includes a printing voltage of -5,000 V to +5,000 V, a printing air pressure of 0 – 500 kPa, a printing speed of 0 – 80 mm/s, and a printing height of 0.04 – 3 mm.

In some other examples, in step 4, the conductive material includes nano silver ink, conductive copper ink/copper paste, silver nanowire ink, carbon paste, a conductive polymer, with a viscosity range of 0 – 10,000 cps.

In some other examples, in step 4, the printing parameters includes a printing voltage of -3,000 V to +3,000 V, a printing air pressure of 0 – 300 kPa, a printing speed of 0 – 50 mm/s, and a printing height of 0.03 – 0.3 mm.

### Example 3

A method for fabricating a curved conformal multilayer circuit by an EFD jet deposition micro-nano 3D printing based on charge-injection electrowetting is provided. In the present example, a non-developable curved ceramic substrate with an area of 20×20 cm² is selected, a structure of a printed circuit is a multi-layer interconnecting circuit, a dielectric material is PDMS, and a conductive material is nano silver paste or stretchable silver paste. The specific implementation steps are as follows.

Step 1: pretreatment of a substrate. First, the ceramic substrate is cleaned to remove surface impurities; then, a scanner is used to perform digital reverse engineering on the printed substrate, a processing model is built, and processing codes are generated according to a required circuit pattern and input to a five-axis linkage micro-nano 3D printer.

Step 2: printing of a first PDMS dielectric layer. A PDMS precursor solution is used as a printing material, the prepared printing material is placed into a conformal dielectric thin film printing nozzle (a stainless steel conductive nozzle is used, and the nozzle is connected to a positive electrode of a high-voltage power supply), and a charge injection and an EFD jet deposition micro-nano 3D printing process are employed, as shown in FIG. 4. The printing nozzle is moved to a printing start point on the substrate, the single-potential nozzle is connected to the positive electrode of the high-voltage power supply, printing parameters (a nozzle inner diameter of 0.2 mm, a printing height of 0.2 mm, a printing voltage of 3000V, a printing air pressure of 200 kPa, and a workbench movement speed of 20 mm/s) are set, a printing path is loaded, and under a charge-injection electrowetting effect, a PDMS dielectric thin film layer is conformally printed on the surface of the ceramic substrate, as shown in FIG. 2B. The dielectric layer is cured by heating.

Step 3: elimination of residual charge. The residual charge in the printed dielectric layer and the substrate is eliminated using an electrostatic eliminator on the five-axis linkage micro-nano 3D printer.

Step 4: printing of a first conductive-layer conformal circuit. Conductive silver paste is used as a printing material, the printing material is placed into a conformal circuit printing nozzle (a glass nozzle is used, and an extraction electrode disposed on an outer side of the nozzle is connected to a positive electrode of a high-voltage power supply), and a non-contact EFD jet deposition micro-nano 3D printing process is employed, as shown in FIG. 5. The printing nozzle is moved to a printing start point on a circuit, printing parameters (a nozzle inner diameter of 0.08 mm, a printing height of 0.15 mm, a printing voltage of -2000V, a printing air pressure of 150 kPa, and a workbench movement speed of 40 mm/s) are set, a printing path is loaded, and the conductive material is formed into a Taylor cone under a self-excited electrostatic field effect to achieve conformal printing of the high-precision circuit, as shown in FIG. 3. Due to no charge injection, the crosstalk is reduced, the printing stability is improved, and the fabrication of a high-resolution and high-density curved conformal microcircuit is achieved. After printing is completed, conductive traces are cured by heating.

Step 5: printing of a second PDMS dielectric layer. The operation of step 2 is performed to print a second (or next) dielectric layer.

Step 6: fabricating of vertical interconnect vias. A plurality of vertical interconnect microvias are fabricated in the second dielectric layer by using a laser printing module.

Step 7: elimination of the residual charge. The operation of step 3 is performed.

Step 8: printing of a conductive-layer conformal circuit and filling of the vertical interconnect vias. The operation of step 4 is performed to print a second conductive-layer circuit. Subsequently, a circuit filling vertical interconnect vias is printed to complete fabrication of a vertical interconnect circuit. Finally, the printed circuit is made conductive through heat curing of the silver paste.

Step 9: the operations of step 5, step 6, step 7, and step 8 are repeated to complete fabrication of all curved conformal dielectric layers and conductive-layer conformal circuits and vertical interconnect circuits.

Step 10: printing a packaging layer. The curved conformal multilayer circuit is packaged.

Step 11, post-treatment. Dustproof and anti-oxidation post-treatments are performed on the multilayer circuit.

In some other examples, in step 1, a material of the curved substrate includes, but is not limited to, ceramic, PEEK, plastic, glass, resin, silicone, metal, or the like, and a shape of the substrate includes, but is not limited to, any 3D curved geometric shape of a developable curved surface or a non-developable curved surface.

In some other examples, in step 2, the dielectric material includes, but is not limited to, ceramic, polyimide (PI), or the like.

In some other examples, in step 2, the printing parameters includes a printing voltage of -5,000 V to +5,000 V, a printing air pressure of 0 – 500 kPa, a printing speed of 0 – 80 mm/s, and a printing height of 0.04 – 3 mm.

In some other examples, in step 4, the conductive material includes nano silver ink, conductive copper ink/copper paste, silver nanowire ink, carbon paste, a conductive polymer, a stretchable carbon paste/conductive polymer, or the like, with a viscosity range of 0 – 10,000 cps.

In some other examples, in step 4, the printing parameters includes a printing voltage of -3,000 V to +3,000 V, a printing air pressure of 0 – 300 kPa, a printing speed of 0 – 50 mm/s, and a printing height of 0.03 – 0.3 mm.

### Example 4

A system for fabricating a curved conformal multilayer circuit includes a five-axis linkage micro-nano 3D printer, and the five-axis linkage micro-nano 3D printer includes a single- potential contact electric field conductive nozzle, a non-contact electric field nozzle, and an electrostatic eliminator.

As shown in FIG. 4, the conformal thin film printing nozzle includes a barrel 3, an adapter 2, and a single-potential nozzle 4, where the single-potential nozzle (a conductive nozzle is used, and the nozzle is connected to a positive electrode of a high-voltage power supply) is disposed at a tail end of the barrel 3, the adapter 2 is disposed at an upper end of the barrel 3, and the barrel 3 is connected to an air pressure module 1.

As shown in FIG. 5, the conformal circuit printing nozzle (the non-contact EFD jet deposition 3D printing nozzle) includes a barrel 3, an adapter 2, an insulating printing nozzle 4, and an annular electrode 5, where the insulating printing nozzle (made of glass, ceramic, or the like) is disposed at a tail end of the barrel 3, the annular electrode (connected to a positive electrode of a high-voltage power supply) is sleeved outside the insulating printing nozzle, the adapter 2 is disposed at an upper end of the barrel 3, and the barrel 3 is connected to an air pressure module 1.

The conformal thin film printing nozzle, the conformal circuit printing nozzle, the electrostatic eliminator, and the laser printing module are arranged side by side.

An optional range for an inner diameter of the printing nozzle of the conformal thin film printing nozzle is 0.1 – 0.6 mm, and the printing nozzle is made of a conductive material and is externally connected to a high-voltage power supply with an adjustable range of -5,000 V to +5,000 V.

The printing nozzle of the conformal circuit printing nozzle is made of a non-conductive material, and the annular electrode 5 is fixed on an outer side of the printing nozzle 4 without direct contact with a printing material.

As an alternative embodiment, an optional range for an inner diameter of the printing nozzle of the conformal circuit printing nozzle is 0.1 – 0.6 mm, and the annular electrode is connected to a high-voltage power supply with an adjustable range of -5,000 V to +5,000 V.

As an alternative embodiment, a pressure range of the air pressure module is 0 – 500 kPa.

The above descriptions are only preferred embodiments of the present invention and are not used to limit the present invention. For those skilled in the art, the present invention may have various modifications and variations. Any modifications, equivalent substitutions, improvements, etc. made by those skilled in the art within the spirit and principle of the present invention without creative efforts shall be included within the scope of protection of the present invention.

1. A method for fabricating a curved conformal multilayer circuit by an electric-field-driven (EFD) jet deposition micro-nano 3-dimensional (3D) printing based on charge control, comprising the following steps:
step (1): pretreating a substrate, comprises degreasing and decontaminating the substrate, and then fixing the substrate after the treatment to a printing platform;
step (2): printing a dielectric layer, comprises selecting a dielectric material according to design requirements, placing a prepared printing material into a conformal thin-film dielectric layer printing nozzle, printing a first dielectric layer through a charge injection and an EFD jet deposition micro-nano 3D printing process in combination with optimized process parameters, and fabricating a high-precision curved conformal thin-film dielectric layer through active charge injection and a charge-injection electrowetting effect in combination with the EFD jet deposition micro-nano 3D printing;
step (3): eliminating residual charge in the printed dielectric layer and the substrate;
step (4): printing a conductive-layer conformal circuit, comprises selecting a conductive ink, placing the selected conductive ink into a conformal circuit printing nozzle, printing a first conductive-layer conformal circuit through a non-contact EFD jet deposition micro-nano 3D printing process in combination with the optimized process parameters, and making the printed circuit conductive through curing and sintering treatments;
step (5): printing a dielectric layer, comprises performing the operation of step (2) to print a second or next dielectric layer;
step (6): fabricating vertical interconnect vias, comprises fabricating a plurality of vertical interconnect microvias in the second dielectric layer by using a laser printing module;
step (7): eliminating the residual charge;
step (8): printing a conductive-layer conformal circuit and filling the vertical interconnect vias, comprises performing the operation of step (4) to print a second conductive-layer conformal circuit, then printing a circuit filling the vertical interconnect vias to complete fabrication of a vertical interconnect circuit, and making the printed conformal circuit conductive through curing and sintering treatments;
step (9): repeating the operations of step (5) to step (8) to complete fabrication of all curved conformal dielectric layers and conductive-layer conformal circuits and interlayer vertical interconnect circuits;
step (10): printing a packaging layer; and
step (11): performing a post-treatment.

2. The method for fabricating the curved conformal multilayer circuit by the EFD jet deposition micro-nano 3D printing based on charge control according to claim 1, wherein in the step (1), a material of the substrate comprises one of ceramic, polyetheretherketone (PEEK), plastic, glass, resin, silicone, and metal, and a shape of the substrate comprises any 3D curved geometric shape of a developable curved surface or a non-developable curved surface.

3. The method for fabricating the curved conformal multilayer circuit by the EFD jet deposition micro-nano 3D printing based on charge control according to claim 1, wherein in the step (2), the dielectric material comprises at least one of polyimide (PI), polytetrafluoroethylene (PTFE), a liquid crystal polymer (LCP), resin, polydimethylsiloxane (PDMS), and ceramic, with a viscosity range of 1 – 50,000 cps.

4. The method for fabricating the curved conformal multilayer circuit by the EFD jet deposition micro-nano 3D printing based on charge control according to claim 1, wherein in the step (2), in the charge injection and the EFD jet deposition micro-nano 3D printing process, a conductive nozzle is directly connected to a high-voltage power supply; and
the optimized process parameters comprise a printing voltage of -5,000 V to +5,000 V, a printing air pressure of 0 – 500 kPa, a printing speed of 0 – 80 mm/s, and a printing height of 0.04 – 3 mm.

5. The method for fabricating the curved conformal multilayer circuit by the EFD jet deposition micro-nano 3D printing based on charge control according to claim 1, wherein in the step (4), a conductive material comprises at least one of nano silver ink/silver paste, conductive copper ink/copper paste, silver nanowire ink, carbon paste, and a conductive polymer, with a viscosity range of 1 – 50,000 cps.

6. The method for fabricating the curved conformal multilayer circuit by the EFD jet deposition micro-nano 3D printing based on charge control according to claim 1, wherein in the step (4), in the non-contact EFD jet deposition micro-nano 3D printing process, a glass or ceramic insulating nozzle is used, and an extraction electrode disposed on an outer side of the nozzle is connected to a positive electrode of a high-voltage power supply; and
the optimized process parameters comprise a printing voltage of -3,000 V to +3,000 V, a printing air pressure of 0 – 300 kPa, a printing speed of 0 – 50 mm/s, and a printing height of 0.03 – 0.5 mm.

7. The method for fabricating the curved conformal multilayer circuit by the EFD jet deposition micro-nano 3D printing based on charge control according to claim 1, wherein in the step (8), a high-solid-content stretchable conductive material is selected as the printing material and comprises at least one of stretchable silver paste, stretchable carbon paste, and a conductive polymer, with a solid content greater than 60% and a viscosity range of 0 – 50,000 cps; and
printing parameters comprise a printing voltage of 0 – 2,000 V, a printing air pressure of 0 – 500 kPa, and a printing speed of 0 – 20 mm/s.

8. A system for fabricating a curved conformal multilayer circuit by an electric-field-driven (EFD) jet deposition micro-nano 3D printing based on charge control, comprising a five-axis linkage micro-nano 3D printer, a laser drilling module, and a control system, wherein
the five-axis linkage micro-nano 3D printer comprises a single-potential contact electric field conductive nozzle, a non-contact electric field nozzle, and an electrostatic eliminator; wherein,
the single-potential contact electric field conductive nozzle comprises a barrel, an adapter, and a printing nozzle, the conductive printing nozzle is disposed at a tail end of the barrel, the adapter is disposed at an upper end of the barrel, and the barrel is connected to an air pressure module;
the non-contact electric field nozzle comprises a barrel, an adapter, a printing nozzle, and an annular electrode, the printing nozzle is disposed at a tail end of the barrel, the annular electrode is sleeved outside the printing nozzle, the adapter is disposed at an upper end of the barrel, and the barrel is connected to an air pressure module; and
the electrostatic eliminator is arranged side by side with the single-potential contact electric field conductive nozzle and the non-contact electric field nozzle, or is automatically switched using an automatic switching device.

9. The system for fabricating the curved conformal multilayer circuit by the EFD jet deposition micro-nano 3D printing based on charge control according to claim 8, wherein an optional range for an inner diameter of the printing nozzle of the single-potential contact electric field conductive nozzle is 0.1 – 0.6 mm, and the printing nozzle is made of a conductive material and is externally connected to a high-voltage power supply with an adjustable range of -5,000 V to +5,000 V.

10. The system for fabricating the curved conformal multilayer circuit by the EFD jet deposition micro-nano 3D printing based on charge control according to claim 8, wherein the printing nozzle of the non-contact electric field nozzle is made of a non-conductive material, and the annular electrode is fixed on an outer side of the printing nozzle without direct contact with a printing material;
an optional range for an inner diameter of the printing nozzle of the non-contact electric field nozzle is 0.1 – 0.6 mm, and the annular electrode is connected to a high-voltage power supply with an adjustable range of -5,000 V to +5,000 V; and
a pressure range of the air pressure module is 0 – 500 kPa.
